(19) United States
(12) Patent Application Publication
(10) Pub. No.: US 2013/0026586 A1
(43) Pub. Date: Jan. 31, 2013

(54) CROSS-LOOP ANTENNA

(71) Applicants: Eunyoung Seok, Plano, TX (US); Srinath Ramaswamy, Murphy, TX (US); Brian P. Ginsburg, Allen, TX (US); Vijay B. Rentala, Plano, TX (US); Baher Haroun, Allen, TX (US)

(72) Inventors: Eunyoung Seok, Plano, TX (US); Srinath Ramaswamy, Murphy, TX (US); Brian P. Ginsburg, Allen, TX (US); Vijay B. Rentala, Plano, TX (US); Baher Haroun, Allen, TX (US)

(73) Assignee: Texas Instruments Incorporated, Dallas, TX (US)

(21) Appl. No.: 13/191,157

(22) Filed: Jul. 26, 2011

(51) Int. Cl. H01L 31/115; H05K 1/11; H05K 1/00

(52) U.S. Cl. 257/428; 174/250; 174/266; 257/E31.086

(57) ABSTRACT

An antenna is provided. This antenna is contained within a package that is secured to an IC (which allows radiation to propagated away for a printed circuit board so as to reduce interference), and this antenna includes two loop antennas that are shorted to ground and that “overlap” and includes a “via wall.” With this configuration, circular polarization can be achieved by varying the relative phases of the input signals, and the “via wall” improves efficiency by reducing surface waves.

TECHNICAL FIELD

The invention relates generally to a loop antenna and, more particularly, to a loop antenna for use in the terahertz frequency range.

### BACKGROUND

Loop antennas have been used in a wide variety of applications over the years, but, for high frequency applications (i.e., terahertz radiation) and for monolithically integrated antennas, there can be a variety of barriers to the use of loops antennas. For example, there can be loses associated with packaging material between the antenna and transmission media. Another example is losses due to parasitic radiation and interface from trances in printed circuit boards or PCBs. Therefore, there is a need for an improved system. Some examples of conventional systems are: U.S. Pat. No. 7,545,329; and J. Grzyb, D. Liu, U. Pfeiffer, and B. Gaucher, “Wideband cavity-backed folded dipole superstrate antenna for 60 GHz applications,” Proceedings of the 2006 IEEE AP-S International Symposium and UNSC/URSI and AMEREM Meetings, pp. 3939-3942, Albuquerque, N.M., Jul. 9-14, 2006.

### SUMMARY

An embodiment of the present invention, accordingly, provides an apparatus. The apparatus comprises a substrate having a first terminal, a second terminal, third terminal, and a fourth terminal; a first metallization layer disposed over the substrate, wherein the first metallization layer includes: a first window region; a first conductive region disposed over and in electrical contact with the first terminal, wherein the first conductive region is substantially circular, and wherein the first conductive region is located within the first window region; a second conductive region disposed over and in electrical contact with the second terminal, wherein the second conductive region is substantially circular, and wherein the first conductive region is located within the first window region; a third conductive region disposed over and in electrical contact with the third terminal, wherein the third conductive region is substantially circular, and wherein the third conductive region is located within the first window region; and a fourth conductive region disposed over and in electrical contact with the fourth terminal, wherein the fourth conductive region is substantially circular, and wherein the fourth conductive region is located within the first window region; a second metallization layer disposed over the first metallization layer, wherein the second metallization layer includes: a second window region that is substantially aligned with the first window region; a fifth conductive region disposed over and in electrical contact with the first conductive region, wherein the fifth conductive region is substantially circular, and wherein the fifth conductive region is located within the second window region; a sixth conductive region disposed over and in electrical contact with the second conductive region, wherein the sixth conductive region is substantially circular, and wherein the sixth conductive region is located within the second window region; a seventh conductive region disposed over and in electrical contact with the third conductive region, wherein the seventh conductive region is substantially circular, and wherein the seventh conductive region is located within the second window region; an eighth conductive region disposed over and in electrical contact with the fourth conductive region, wherein the eighth conductive region is substantially circular, and wherein the fourth conductive region is located within the second window region; and a ninth conductive region that extends between and is in electrical contact with the fifth and eighth conductive regions; and a third metallization layer disposed over the second metallization layer, wherein the third metallization layer includes: a third window region that is substantially aligned with the second window region; a tenth conductive region disposed over and in electrical contact with the fifth conductive region, wherein the tenth conductive region is substantially circular, and wherein the tenth conductive region is located within the third window region; an eleventh conductive region disposed over and in electrical contact with the sixth conductive region, wherein the eleventh conductive region is substantially circular, and wherein the eleventh conductive region is located within the third window region; a twelfth conductive region disposed over and in electrical contact with the seventh conductive region, wherein the twelfth conductive region is substantially circular, and wherein the twelfth conductive region is located within the third window region; a thirteenth conductive region disposed over and in electrical contact with the eighth conductive region, wherein the thirteenth conductive region is substantially circular, and wherein the thirteenth conductive region is located third the second window region; and a fourteenth conductive region that extends between and is in electrical contact with the eleventh and twelfth conductive regions, wherein the fourteenth region overlaps the ninth region.

In accordance with an embodiment of the present invention, the first, second, and third window regions are substantially rectangular.

In accordance with an embodiment of the present invention, the apparatus further comprises: a first set of vias, wherein each via from the first set of via extends between at least one of the first and fifth conductive regions, the second and sixth conductive regions, the third and seventh conductive regions, and the fourth and eighth conductive regions; and a second set of vias, wherein each via from the second set of via extends between at least one of the tenth and fifth conductive regions, the eleventh and sixth conductive regions, the twelfth and seventh conductive regions, and the thirteenth and eighth conductive regions.

In accordance with an embodiment of the present invention, the substrate further comprises a plurality of border terminals, and wherein the first metallization layer further comprises a fifteenth conductive region that substantially surrounds the first window region and is in electrical contact with the boarder terminals, and wherein the second metallization layer further comprises a sixteenth conductive region that substantially surrounds the second window region and that is in electrical contact with the fifteenth conductive region, and wherein the third metallization layer further comprises a seventeenth conductive region that substantially surrounds the third window region and that is in electrical contact with the sixteenth conductive region.

In accordance with an embodiment of the present invention, the apparatus further comprises: a third set of vias, wherein each via from the third set of vias extends between the fifteenth and sixteenth conductive regions; and a fourth set of vias, wherein each via from the fourth set of vias extends between the sixteenth and seventeenth conductive regions.

In accordance with an embodiment of the present invention, the first and second terminals are coupled to ground.

In accordance with an embodiment of the present invention, the first, second, third and fourth terminals are stud bumps.

In accordance with an embodiment of the present invention, an apparatus is provided. The apparatus comprises an integrated circuit (IC) having: radio frequency (RF) circuitry; a stud bump that is coupled to the RF circuitry; a second stud bump that is coupled to the RF circuitry; a third stud bump that is coupled to the RF circuitry and that is coupled to ground; a fourth stud bump that is coupled to the RF circuitry and that is coupled to ground; and an antenna package having: a dielectric layer, wherein the first, second, third, and fourth stud bumps extend through the dielectric layer; an underfill layer that is disposed between the dielectric layer and the IC; a first metallization layer disposed over the substrate, wherein the first metallization layer includes: a first window region; a first conductive region disposed over and in electrical contact with the first stud bump, wherein the first conductive region is substantially circular, and wherein the first conductive region is located within the first window region; a second conductive region disposed over and in electrical contact with the second stud bump, wherein the second conductive region is substantially circular, and wherein the first conductive region is located within the first window region; a third conductive region disposed over and in electrical contact with the third stud bump, wherein the third conductive region is substantially circular, and wherein the third conductive region is located within the first window region; and a fourth conductive region disposed over and in electrical contact with the fourth stud bump, wherein the fourth conductive region is substantially circular, and wherein the fourth conductive region is located within the first window region; a package substrate; a second metallization layer disposed over the package substrate, wherein the first metallization layer includes: a second window region that is substantially aligned with the first window region; a fifth conductive region disposed over and in electrical contact with the first conductive region, wherein the fifth conductive region is substantially circular, and wherein the fifth conductive region is located within the second window region; a sixth conductive region disposed over and in electrical contact with the second conductive region, wherein the sixth conductive region is substantially circular, and wherein the sixth conductive region is located within the second window region; a seventh conductive region disposed over and in electrical contact with the third conductive region, wherein the seventh conductive region is substantially circular, and wherein the seventh conductive region is located within the second window region; and an eighth conductive region disposed over and in electrical contact with the fourth conductive region, wherein the eighth conductive region is substantially circular, and wherein the eighth conductive region is located within the second window region; a set of vias, wherein each via from the set of via extends through the package substrate between at least one of the first and fifth conductive regions, the second and sixth conductive regions, the third and seventh conductive regions, and the fourth and eighth conductive regions; a second metallization layer disposed over the first metallization layer, wherein the second metallization layer includes: a third window region that is substantially aligned with the second window region; a ninth conductive region disposed over and in electrical contact with the fifth conductive region, wherein the ninth conductive region is substantially circular, and wherein the ninth conductive region is located within the third window region; a tenth conductive region disposed over and in electrical contact with the sixth conductive region, wherein the tenth conductive region is substantially circular, and wherein the tenth conductive region is located within the third window region; an eleventh conductive region disposed over and in electrical contact with the seventh conductive region, wherein the eleventh conductive region is substantially circular, and wherein the eleventh conductive region is located within the third window region; a twelfth conductive region disposed over and in electrical contact with the eighth conductive region, wherein the twelfth conductive region is substantially circular, and wherein the twelfth conductive region is located within the third window region; and a thirteenth conductive region that extends between and is in electrical contact with the ninth and twelfth conductive regions; and a third metallization layer disposed over the second metallization layer, wherein the third metallization layer includes: a fourth window region that is substantially aligned with the third window region; a fourteenth conductive region disposed over and in electrical contact with the ninth conductive region, wherein the fourteenth conductive region is substantially circular, and wherein the fourteenth conductive region is located within the fourth window region; a fifteenth conductive region disposed over and in electrical contact with the tenth conductive region, wherein the fifteenth conductive region is substantially circular, and wherein the fifteenth conductive region is located within the fourth window region; a sixteenth conductive region disposed over and in electrical contact with the eleventh conductive region, wherein the sixteenth conductive region is substantially circular, and wherein the sixteenth conductive region is located within the fourth window region; a seventeenth conductive region disposed over and in electrical contact with the twelfth conductive region, wherein the sixteenth conductive region is substantially circular, and wherein the sixteenth conductive region is located third the fourth window region; and an eighteenth conductive region that extends between and is in electrical contact with the fifteenth and sixteenth conductive regions, wherein the eighteenth region overlaps the thirteenth region.

In accordance with an embodiment of the present invention, the first, second, third, and fourth window regions are substantially rectangular.

In accordance with an embodiment of the present invention, the set of via further comprises a first set of vias, and wherein the antenna package further comprises: a second set of vias, wherein each via from the second set of via extends between at least one of the ninth and fifth conductive regions, the tenth and sixth conductive regions, the eleventh and seventh conductive regions, and the twelfth and eighth conductive regions; and a third set of vias, wherein each via from the third set of via extends between at least one of the ninth and fourteenth conductive regions, the tenth and fifteenth conductive regions, the eleventh and sixteenth conductive regions, and the twelfth and seventeenth conductive regions.

In accordance with an embodiment of the present invention, the IC further comprises a plurality of border stud bumps, and wherein the first metallization layer further comprises a nineteenth conductive region that substantially surrounds the first window region and is in electrical contact with the boarder stud bumps, and wherein the second metallization layer further comprises a twentieth conductive region that substantially surrounds the second window region and that is in electrical contact with the nineteenth conductive region, and wherein the third metallization layer further comprises a twenty-first conductive region that substantially surrounds the third window region and that is in electrical contact with the twentieth conductive region.

In accordance with an embodiment of the present invention, the antenna package further comprises: a fourth set of vias, wherein each via from the fourth set of vias extends between the nineteenth and twentieth conductive regions; and a fifth set of vias, wherein each via from the fifth set of vias extends between the twentieth and twenty-first conductive regions.

In accordance with an embodiment of the present invention, the first, second, third, and fourth metallization layers are formed of copper or aluminum, and wherein the dielectric layer is formed of polyimide, and wherein each of the first, second, third, fourth, and border stud bumps are formed of gold with a gold-nickel plating.

In accordance with an embodiment of the present invention, an apparatus is provided. The apparatus comprises an integrated circuit (IC) having: a plurality of RF transceivers; a plurality of sets of stub bumps, wherein each set of stud bump is associated with at least one of the RF transceivers, and wherein each set of stud bumps includes: a first stud bump that is coupled to its associated RF transceiver; a second stud bump that is coupled to its associated RF transceiver; a third stud bump that is coupled to its associated RF transceiver and that is coupled to ground; and a fourth stud bump that is coupled to its associated RF transceiver and that is coupled to ground; an antenna package having: a dielectric layer, wherein each stud bump from each set of the plurality of sets of stud bumps extends through the dielectric layer; an underfill layer that is disposed between the dielectric layer and the IC; a package substrate; an array of antenna, wherein each antenna is associated with at least of the RF transceivers, and wherein each antenna includes: a first metallization layer disposed over the substrate, wherein the first metallization layer includes: a first window region; a first conductive region disposed over and in electrical contact with its associated first stud bump, wherein the first conductive region is substantially circular, and wherein the first conductive region is located within the first window region; a second conductive region disposed over and in electrical contact with its associated second stud bump, wherein the second conductive region is substantially circular, and wherein the first conductive region is located within the first window region; a third conductive region disposed over and in electrical contact with its associated third stud bump, wherein the third conductive region is substantially circular, and wherein the third conductive region is located within the first window region; and a fourth conductive region disposed over and in electrical contact with its associated fourth stud bump, wherein the fourth conductive region is substantially circular, and wherein the fourth conductive region is located within the first window region; a second metallization layer disposed over the package substrate, wherein the first metallization layer includes: a second window region that is substantially aligned with the first window region; a fifth conductive region disposed over and in electrical contact with the first conductive region, wherein the fifth conductive region is substantially circular, and wherein the fifth conductive region is located within the second window region; a sixth conductive region disposed over and in electrical contact with the second conductive region, wherein the sixth conductive region is substantially circular, and wherein the sixth conductive region is located within the second window region; a seventh conductive region disposed over and in electrical contact with the third conductive region, wherein the seventh conductive region is substantially circular, and wherein the seventh conductive region is located within the second window region; and an eighth conductive region disposed over and in electrical contact with the fourth conductive region, wherein the eighth conductive region is substantially circular, and wherein the eighth conductive region is located within the second window region; a set of vias, wherein each via from the set of via extends through the package substrate between at least one of the first and fifth conductive regions, the second and sixth conductive regions, the third and seventh conductive regions, and the fourth and eighth conductive regions; a second metallization layer disposed over the first metallization layer, wherein the second metallization layer includes: a third window region that is substantially aligned with the second window region; a ninth conductive region disposed over and in electrical contact with the fifth conductive region, wherein the ninth conductive region is substantially circular, and wherein the ninth conductive region is located within the third window region; a tenth conductive region disposed over and in electrical contact with the sixth conductive region, wherein the tenth conductive region is substantially circular, and wherein the tenth conductive region is located within the third window region; an eleventh conductive region disposed over and in electrical contact with the seventh conductive region, wherein the eleventh conductive region is substantially circular, and wherein the eleventh conductive region is located within the third window region; a twelfth conductive region disposed over and in electrical contact with the eighth conductive region, wherein the twelfth conductive region is substantially circular, and wherein the twelfth conductive region is located within the third window region; and a thirteenth conductive region that extends between and is in electrical contact with the ninth and twelfth conductive regions; and a third metallization layer disposed over the second metallization layer, wherein the third metallization layer includes: a fourth window region that is substantially aligned with the third window region; a fourteenth conductive region disposed over and in electrical contact with the ninth conductive region, wherein the fourteenth conductive region is substantially circular, and wherein the fourteenth conductive region is located within the fourth window region; a fifteenth conductive region disposed over and in electrical contact with the tenth conductive region, wherein the fifteenth conductive region is substantially circular, and wherein the fifteenth conductive region is located within the fourth window region; a sixteenth conductive region disposed over and in electrical contact with the eleventh conductive region, wherein the sixteenth conductive region is substantially circular, and wherein the sixteenth conductive region is located within the fourth window region; a seventeenth conductive region disposed over and in electrical contact with the twelfth conductive region, wherein the sixteenth conductive region is substantially circular, and wherein the sixteenth conductive region is located third the fourth window region; and an eighteenth conductive region that extends between and is in electrical contact with the fifteenth and sixteenth conductive regions, wherein the eighteenth region overlaps the thirteenth region; and a high impedance surface (HIS) disposed on the substrate and substantially surrounding the array of antennas.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a system in accordance with a preferred embodiment of the present invention;

FIG. 2 is a plan view of the antenna package of FIG. 1;

FIG. 3 is a plan view of the bottom dielectric layer for an antenna of FIG. 2;

FIG. 4 is a cross-sectional view of FIG. 2 along section line I-I;

FIGS. 5, 7, 9, and 11 are plan views of the metallization layers for the antenna of FIG. 2;

FIGS. 6, 8, 10, and 12 are a cross-sectional views of FIGS. 5, 7, 9, and 11 along section lines II-II, III-III, IV-IV, and V-V, respectively; and

FIG. 13 is a diagram depicting an example of the radiation pattern for the antenna of FIG. 2.

### DETAILED DESCRIPTION

Refer now to the drawings wherein depicted elements are, for the sake of clarity, not necessarily shown to scale and wherein like or similar elements are designated by the same reference numeral through the several views.

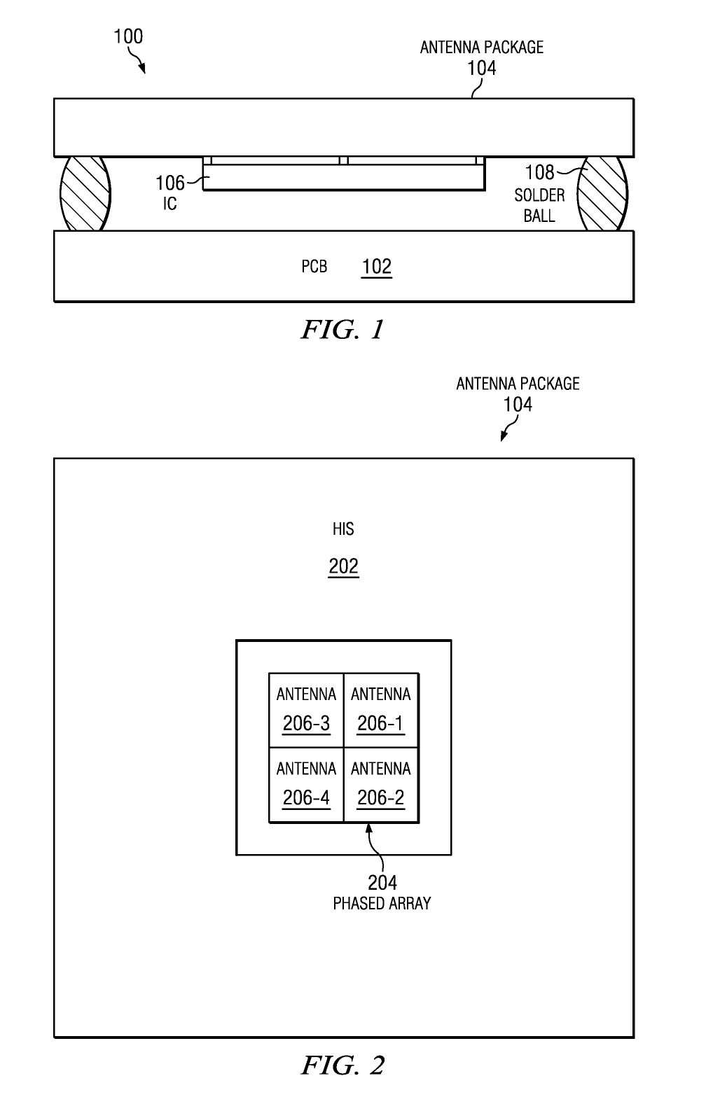

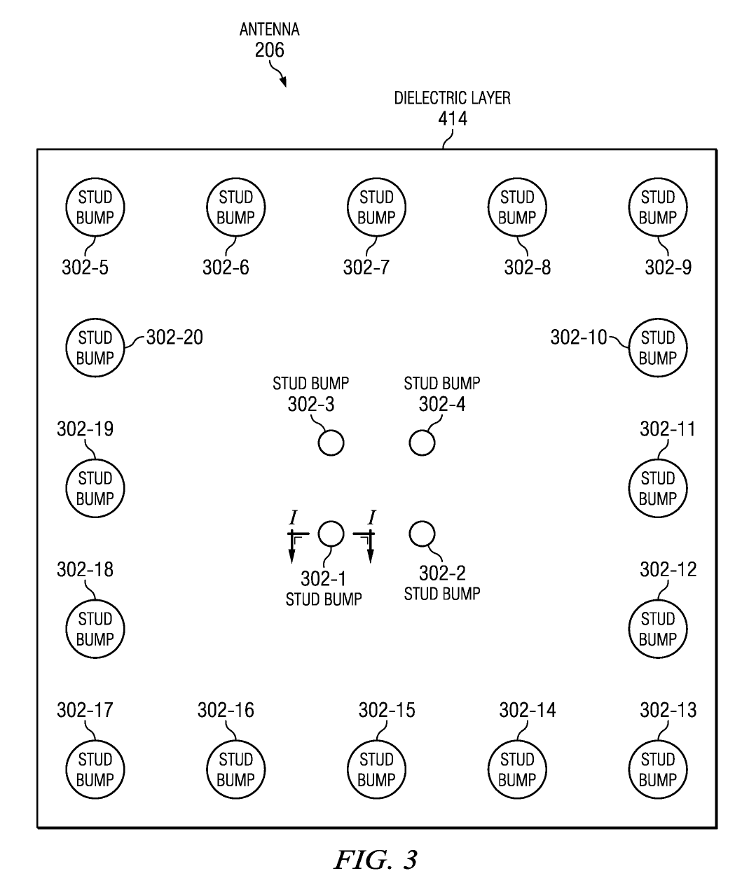

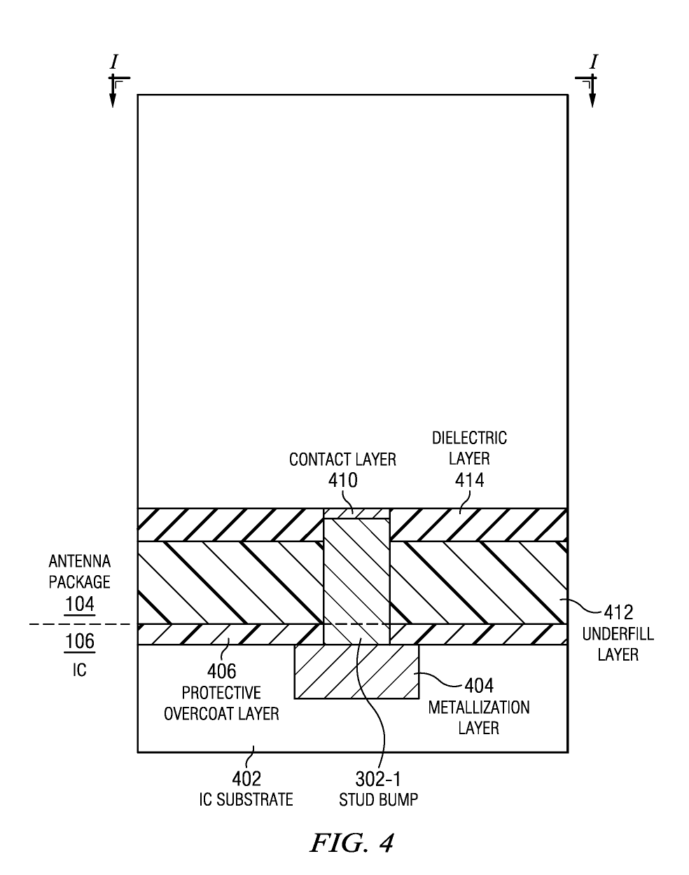

Turning to FIG. 1, an example of a system 100 in accordance with an embodiment of the present invention can be seen. This system 100 generally comprises a printed circuit board (PCB) 102, an antenna package 104, and an integrated circuit (IC) 106. The IC 106 generally includes radio frequency (RF) circuitry. For example, IC 106 can be a terahertz phased array system that includes multiple transceivers. An example of such an IC can be seen in co-pending U.S. patent application Ser. No. 12/878,484, which is entitled “Terahertz Phased Array System,” filed on Sep. 9, 2010, and is hereby incorporated by reference for all purposes. This IC 106 is then secured to the antenna packages 104 to allow each transceiver (for example) to communicate with an antenna included on the antenna package 104. Typically, the IC 106 has a protective overcoat 406 that covers the IC 106, including metallization layer 404 and IC substrate 402 (as shown in FIGS. 4, 6, 8, 10, and 12), and stud bumps 302-1 to 302-20 (which can be seen in FIGS. 3, 4, 6, 8, 10, and 12) are secured between the IC 106 and antenna package 104. The antenna package 104 can then be secured to the PCB 102 (which is typically accomplished through bondpads being secured to one another through solder balls 108). By using this arrangement, cross-talk and loss can be reduced.

In FIG. 2, an example of the antenna package 104 can be seen in greater detail. As shown, the antenna package includes a phased array 204 that is substantially surrounded by a high impedance surface (HIS). An example of such an HIS can be seen in U.S. patent application Ser. No. 13/116,885, which is entitled “High Impedance Surface,” was filed on May 26, 2011, and is hereby incorporated by reference for all purposes. Also, as shown, the phased array 204 includes antennas 206-1 to 206-4, but any number of antennas is possible. This phased array 204 can then be used to steer the beam of radiation.

In FIGS. 3-12, an example of the structure of each of the antennas 206-1 to 206-4 (hereinafter labeled 206) can be seen. Antenna 206 can be (for example) configured to operate at 160GHz. For this example operating frequency, the area occupied by the antenna (as shown in FIGS. 3-12) can be 1020 μm×1020 μm, and the “core” of the antenna package 106 can be the package substrate 420 (which can, for example, have a thickness of about 160 μm), and this package substrate 420 can also be formed of a polymer with a high elastic modulus and low coefficient of thermal expansion and can have. An example of which can be MCL-E679GT (which is available from Hitachi Chemical Co. America, Ltd.). Layers of differing materials can then be formed on the package substrate 402.

On the underside of package substrate 402 (i.e., between the package substrate 402 and IC 106) a dielectric layer 414 is formed. As shown in FIGS. 3 and 4, dielectric layer 414 (which can be referred to as a bottom dielectric layer) can be formed, for example, of a polyimide with a thickness of about 10 μm. Stud bumps 302-1 to 302-20 extend through the dielectric layer and can be formed of, for example, gold with a gold-nickel contact layer 410. As shown, stud bumps 302-5 to 302-20 are arranged along the perimeter of the antenna 206 (separated from one another, for example, by about 200 μm), while stud bumps 302-1 to 302-4 are arranged symmetrically around the center of antenna 206 and separated from one another (for example) by about 220 μm. Additionally, stud bumps 302-1 and 302-2 are typically coupled to differential feed terminals of a corresponding RF transceiver within IC 106, while stud bumps 302-3 and 302-4 are typically coupled to ground.

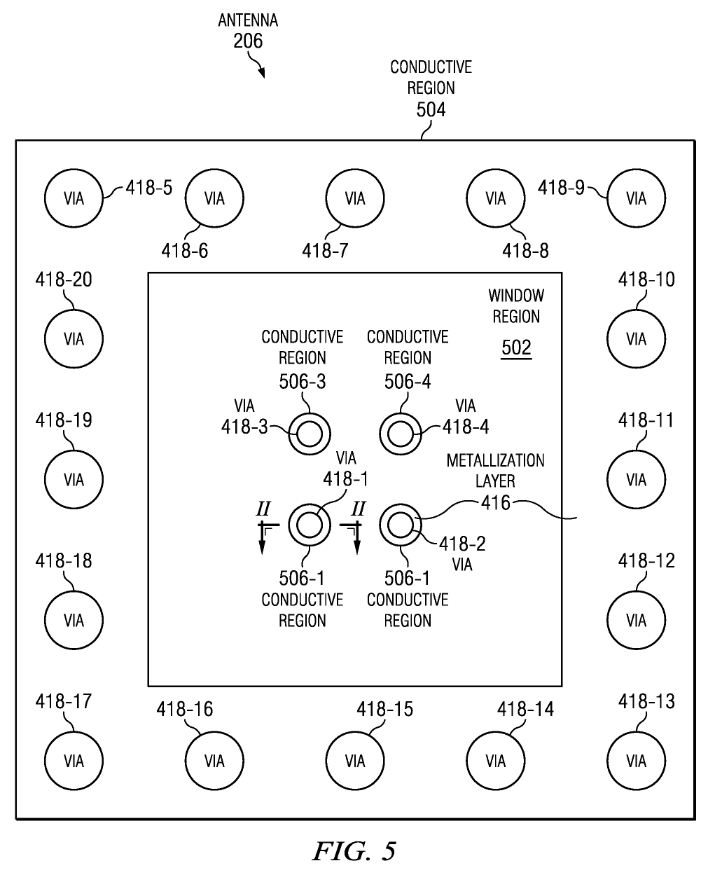

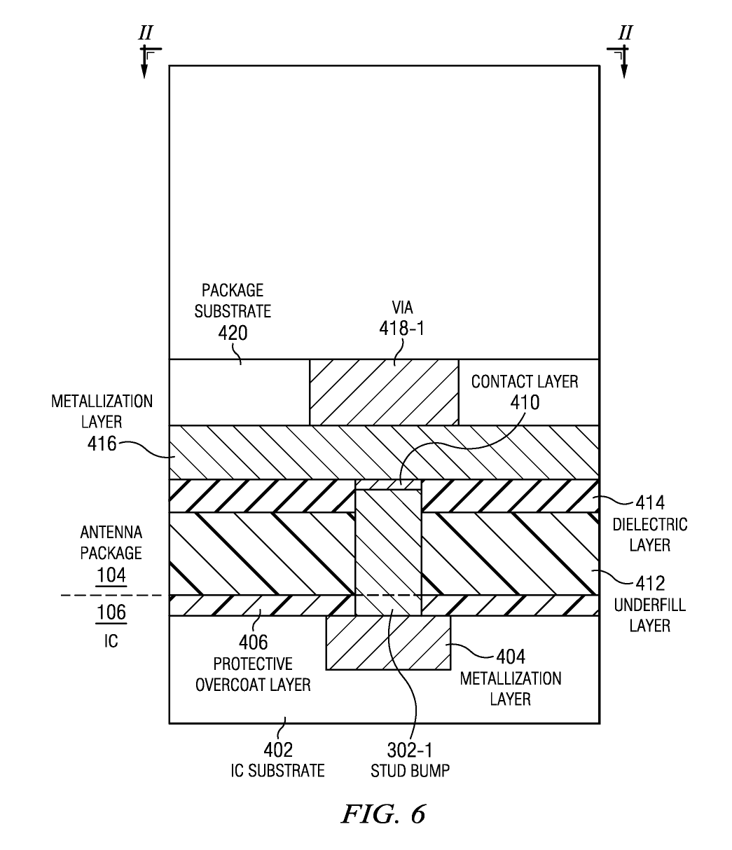

A metallization layer 416 (as shown in FIGS. 5 and 6) is also formed between the dielectric layer 414 and package substrate 420, where this metallization layer 416 can (for example) be formed of aluminum or copper with a thickness of about 17 μm. As shown, metallization layer 416 has a conductive region 504 (which can, for example, be about 180 μm wide) that surrounds window region 502 and has conductive regions 506-1 to 506-4 within window region 502 that are generally aligned with stud bumps 302-1 to 302-4, respectively. These conductive regions 506-1 to 506-4 can (for example) be generally circular with a diameter of about 100 μm. The package substrate 402 also includes vias 418-1 to 418-20 (which are generally aligned with and in electrical contact with conductive region 504 and stud bumps 302-1 to 302-20). Typically, in the manufacture of the antenna package 104, the metallization layer 416 is initially formed on the underside of the package substrate 420 and the dielectric layer 414 is formed over the metallization layer 416, and during assembly of the IC 106 and antenna package 104, an underfill layer 412 can also be formed between the IC 106 and dielectric layer 414 (which can, for example, have a permittivity of about 3.2 C/V*m and a conductivity of 0.011 S/m). This underfill layer 412 can be film applied prior to assembly or can be formed by injection of underfill compound.

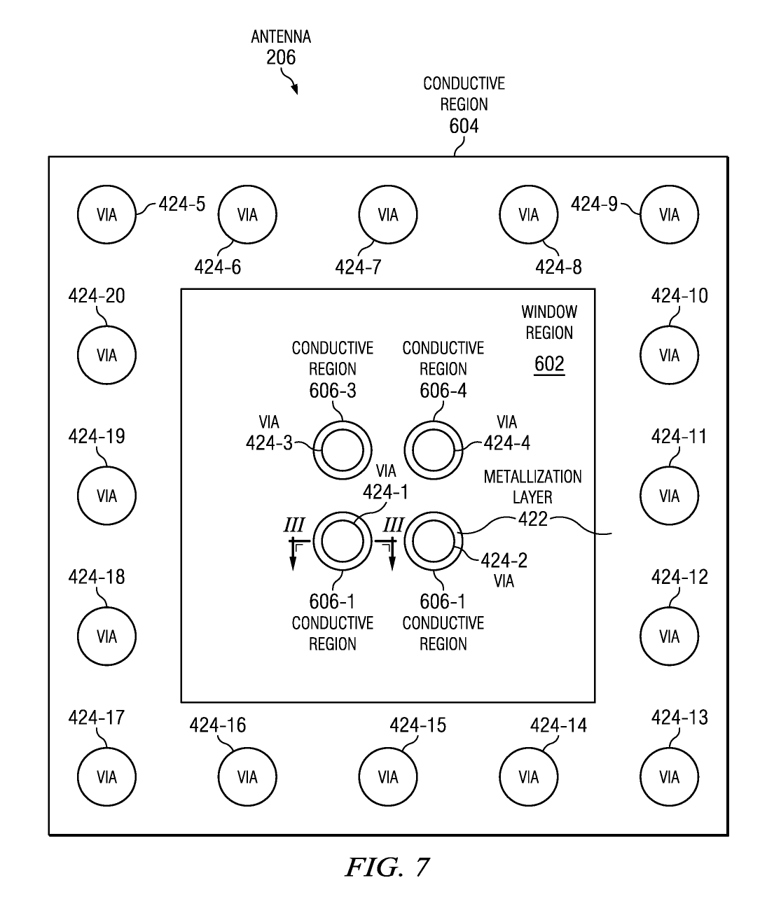

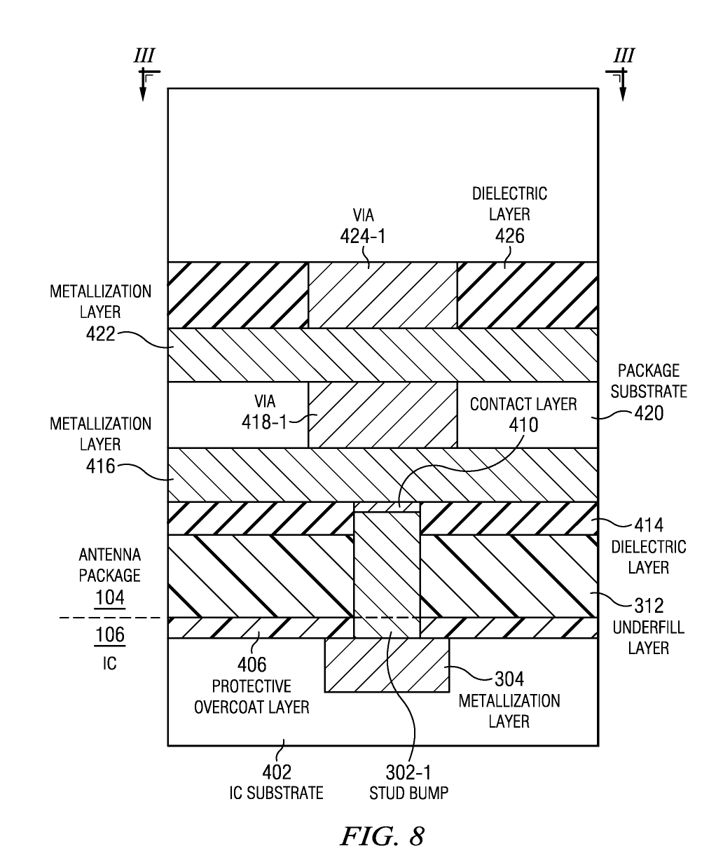

In FIGS. 7 and 8, metallization layer 422 is shown. This metallization layer 422 (similar to metallization layer 416) has a conductive region 604 that substantially surrounds a window region 602 (which the window region 602 can be substantially aligned with window region 502), and this metallization layer 422 can (for example) be formed of aluminum or copper with a thickness of about 17 μm. Within window region 602, there are conductive regions 606-1 to 606-4 that are substantially aligned with vias 418-1 to 418-4, respectively, and are in electrical contact with conductive regions 506-1 to 506-4 through vias 418-1 to 418-4, respectively. Each of these conductive regions 606-1 to 606-4 can also (for example) be generally circular with a diameter of about 180 μm.

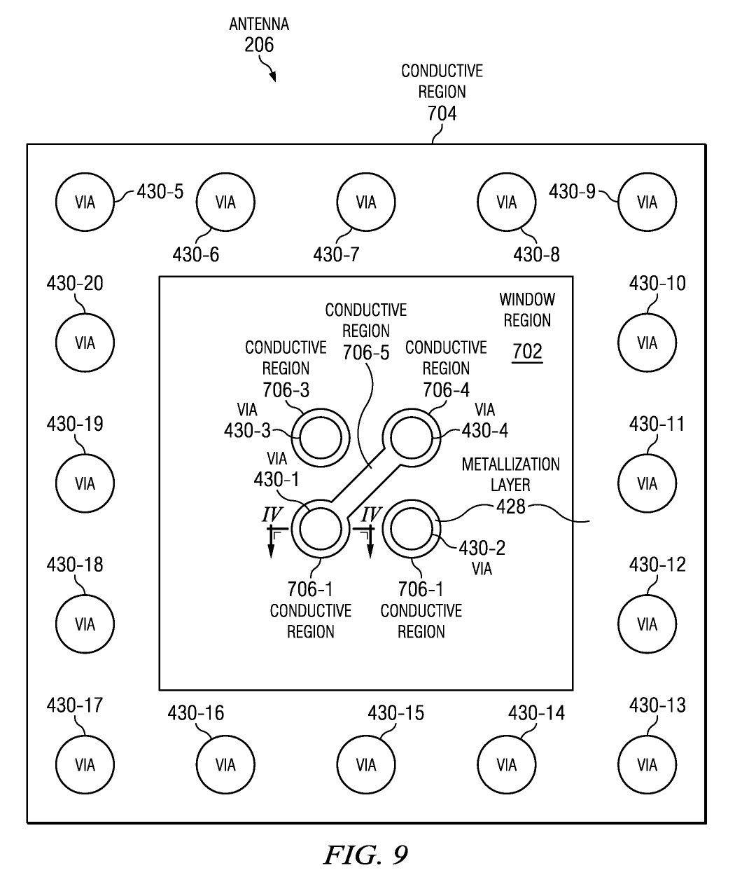

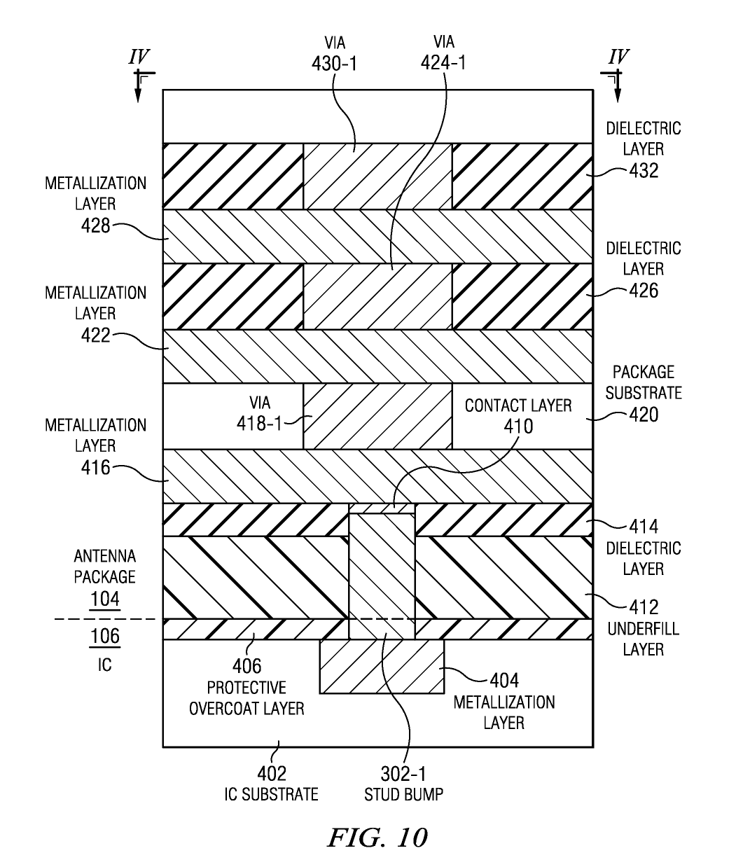

Turning to FIGS. 9 and 10, metallization layer 428 can be seen. This metallization layer 428 (which can, for example, be formed of aluminum or copper with a thickness of about 17 μm) has a conductive region 704 (which can be about 180 μm wide) that substantially surrounds a window region 702 and has conductive regions 706-1 to 706-5 within window region 702. Separating metallization layers 422 and 428 is dielectric layer 426 (which can, for example, be a polyimide film with a thickness of about 20 μm) with vias 424-1 to 424-20 extending therethrough. Conductive regions 706-1 to 706-4 can also be (for example) generally circular with a diameter of about 180 μm, which are aligned with conductive regions 606-1 to 606-4 and vias 424-1 to 424-4, respectively. Additionally, conductive region 706-5 (which can, for example, be about 60 μm wide) extends between and is in electrical contact with conductive regions 706-1 and 706-4 so as to form a connection between one feed terminal from an RF transceiver in IC 106 (i.e., through stud bump 302-1) and ground (i.e., through stud bump 302-4).

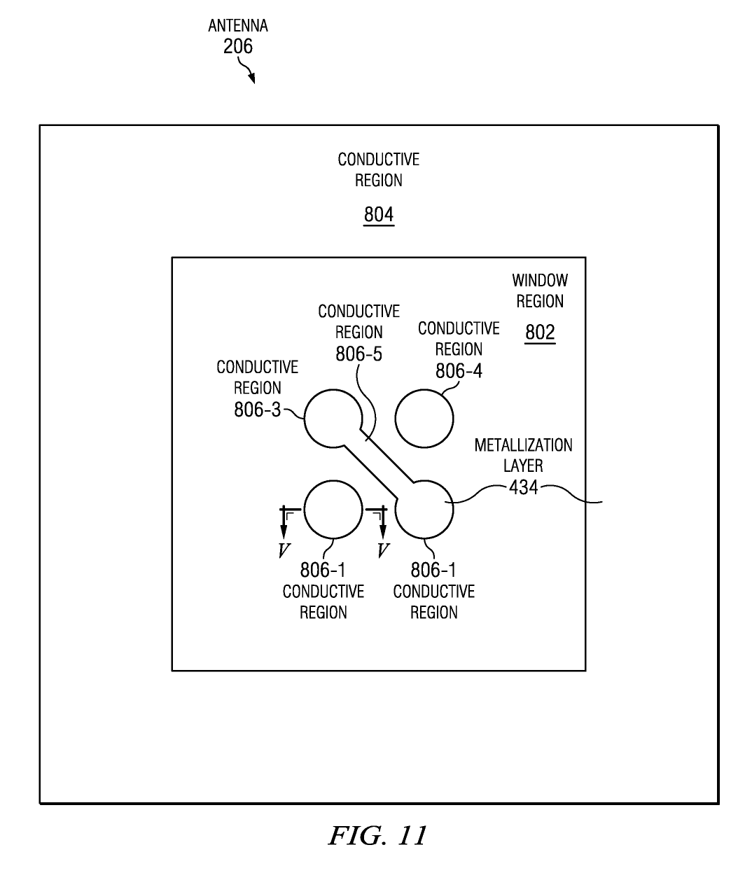

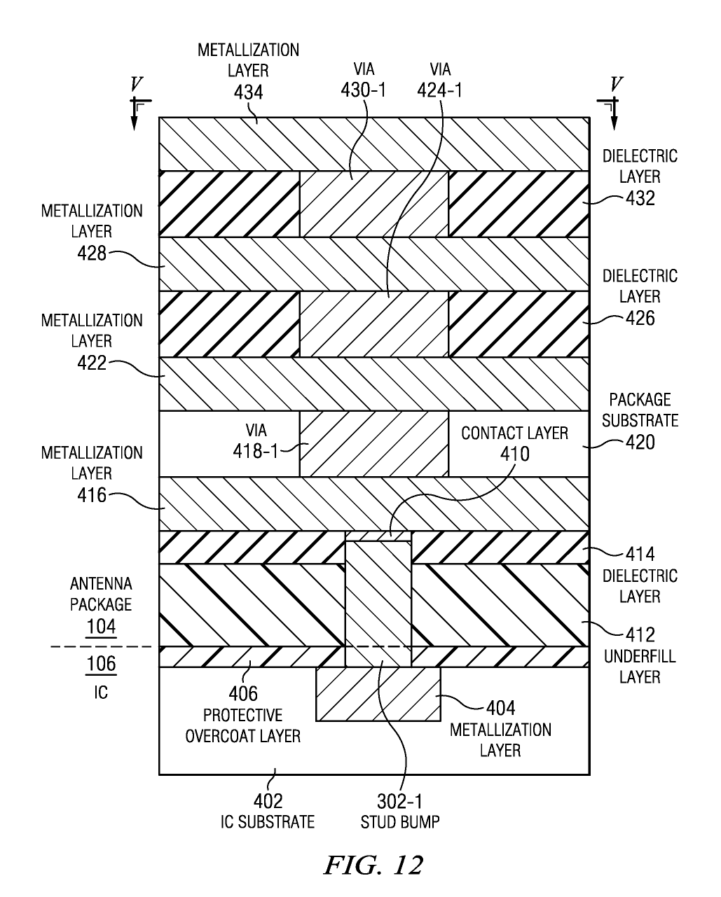

In FIGS. 11 and 12, metallization layer 434 can be seen. As with the other metallization layers (i.e., 422), metallization layers 434 has a conductive region 804 (which can, for example be 180 μm wide and have a thickness, for example of 17 m) that substantially surrounds a window region 802 and that is in electrical contact with conductive region 704 through vias 430-5 to 430-20. Metallization layer 434 also includes conductive regions 806-1 to 806-4 (which can, for example, be generally circular and be about 100 μm in diameter) that are generally aligned with conductive regions 706-1 to 706-4, respectively, and in electrical contact through vias 430-1 to 430-4, respectively. There is also a conductive region 806-5 that extends between and is in electrical contact with conductive regions 806-2 and 806-3 so as to form a connection between one feed terminal from an RF transceiver in IC 106 (i.e., through stud bump 302-2) and ground (i.e., through stud bump 302-3). Because of the orientation of conductive regions 806-5 and 706-5, conductive region 806-5 overlaps conductive region 706-5 to for the “cross loop.”

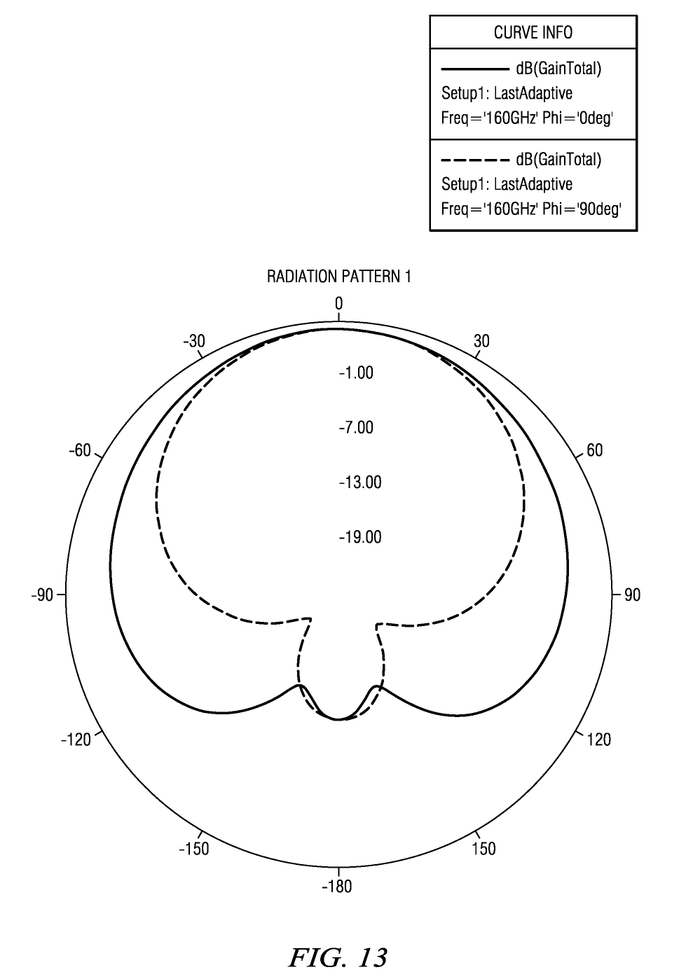

By using this structure to, for example, generate radiation at 160 GHz, the radiation pattern shown in FIG. 13 can be produced. As shown in this example, this is a wide beam with a directivity of 5.2 dBi, a gain of 4.0 dBi, and an efficiency of 76%. Additionally, because of the arrangement of the system 100, radiation propagates away from PCB 102 so that parasitic radiation and interference from PCB trances and be reduced, and the loop antenna (i.e., antenna 206) can allow for circular polarization by varying the phase of the input signal. The “via wall” (which is generally formed by vias 418-5 to 418-20, 424-5 to 424-20, and 430-5 to 430-20) also improves radiation efficiency by reducing surface waves. Moreover, metal layers in both the antenna package 104 and IC 106 can be used to form reflectors and directors to increase antenna gain.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
a substrate having a first terminal, a second terminal, third terminal, and a fourth terminal;
a first metallization layer disposed over the substrate, wherein the first metallization layer includes:
a first window region;
a first conductive region disposed over and in electrical contact with the first terminal, wherein the first conductive region is substantially circular, and wherein the first conductive region is located within the first window region;
a second conductive region disposed over and in electrical contact with the second terminal, wherein the second conductive region is substantially circular, and wherein the first conductive region is located within the first window region;
a third conductive region disposed over and in electrical contact with the third terminal, wherein the third conductive region is substantially circular, and wherein the third conductive region is located within the first window region; and
a fourth conductive region disposed over and in electrical contact with the fourth terminal, wherein the fourth conductive region is substantially circular, and wherein the fourth conductive region is located within the first window region;
a second metallization layer disposed over the first metallization layer, wherein the second metallization layer includes:
a second window region that is substantially aligned with the first window region;
a fifth conductive region disposed over and in electrical contact with the first conductive region, wherein the fifth conductive region is substantially circular, and wherein the fifth conductive region is located within the second window region;
a sixth conductive region disposed over and in electrical contact with the second conductive region, wherein the sixth conductive region is substantially circular, and wherein the sixth conductive region is located within the second window region;
a seventh conductive region disposed over and in electrical contact with the third conductive region, wherein the seventh conductive region is substantially circular, and wherein the seventh conductive region is located within the second window region;
an eighth conductive region disposed over and in electrical contact with the fourth conductive region, wherein the eighth conductive region is substantially circular, and wherein the fourth conductive region is located within the second window region; and
a ninth conductive region that extends between and is in electrical contact with the fifth and eighth conductive regions; and
a third metallization layer disposed over the second metallization layer, wherein the third metallization layer includes:
a third window region that is substantially aligned with the second window region;
a tenth conductive region disposed over and in electrical contact with the fifth conductive region, wherein the tenth conductive region is substantially circular, and wherein the tenth conductive region is located within the third window region;
an eleventh conductive region disposed over and in electrical contact with the sixth conductive region, wherein the eleventh conductive region is substantially circular, and wherein the eleventh conductive region is located within the third window region;
a twelfth conductive region disposed over and in electrical contact with the seventh conductive region, wherein the twelfth conductive region is substantially circular, and wherein the twelfth conductive region is located within the third window region;
a thirteenth conductive region disposed over and in electrical contact with the eighth conductive region, wherein the thirteenth conductive region is substantially circular, and wherein the thirteenth conductive region is located third the second window region; and
a fourteenth conductive region that extends between and is in electrical contact with the eleventh and twelfth conductive regions, wherein the fourteenth region overlaps the ninth region.

2. The apparatus of claim 1, wherein the first, second, and third window regions are substantially rectangular.

3. The apparatus of claim 2, wherein the apparatus further comprises:
a first set of vias, wherein each via from the first set of via extends between at least one of the first and fifth conductive regions, the second and sixth conductive regions, the third and seventh conductive regions, and the fourth and eighth conductive regions; and
a second set of vias, wherein each via from the second set of via extends between at least one of the tenth and fifth conductive regions, the eleventh and sixth conductive regions, the twelfth and seventh conductive regions, and the thirteenth and eighth conductive regions.

4. The apparatus of claim 3, wherein the substrate further comprises a plurality of border terminals, and wherein the first metallization layer further comprises a fifteenth conductive region that substantially surrounds the first window region and is in electrical contact with the boarder terminals, and wherein the second metallization layer further comprises a sixteenth conductive region that substantially surrounds the second window region and that is in electrical contact with the fifteenth conductive region, and wherein the third metallization layer further comprises a seventeenth conductive region that substantially surrounds the third window region and that is in electrical contact with the sixteenth conductive region.

5. The apparatus of claim 4, wherein the apparatus further comprises:
a third set of vias, wherein each via from the third set of vias extends between the fifteenth and sixteenth conductive regions; and
a fourth set of vias, wherein each via from the fourth set of vias extends between the sixteenth and seventeenth conductive regions.

6. The apparatus of claim 5, wherein the first and second terminals are coupled to ground.

7. The apparatus of claim 6, wherein the first, second, third and fourth terminals are stud bumps.

8. An apparatus comprising:
an integrated circuit (IC) having:
radio frequency (RF) circuitry;
a stud bump that is coupled to the RF circuitry;
a second stud bump that is coupled to the RF circuitry;
a third stud bump that is coupled to the RF circuitry and that is coupled to ground;
a fourth stud bump that is coupled to the RF circuitry and that is coupled to ground; and
an antenna package having:
a dielectric layer, wherein the first, second, third, and fourth stud bumps extend through the dielectric layer;
an underfill layer that is disposed between the dielectric layer and the IC;
a first metallization layer disposed over the substrate, wherein the first metallization layer includes:
a first window region;
a first conductive region disposed over and in electrical contact with the first stud bump, wherein the first conductive region is substantially circular, and wherein the first conductive region is located within the first window region;
a second conductive region disposed over and in electrical contact with the second stud bump, wherein the second conductive region is substantially circular, and wherein the first conductive region is located within the first window region;
a third conductive region disposed over and in electrical contact with the third stud bump, wherein the third conductive region is substantially circular, and wherein the third conductive region is located within the first window region; and
a fourth conductive region disposed over and in electrical contact with the fourth stud bump, wherein the fourth conductive region is substantially circular, and wherein the fourth conductive region is located within the first window region;
a package substrate;
a second metallization layer disposed over the package substrate, wherein the first metallization layer includes:
a second window region that is substantially aligned with the first window region;
a fifth conductive region disposed over and in electrical contact with the first conductive region, wherein the fifth conductive region is substantially circular, and wherein the fifth conductive region is located within the second window region;
a sixth conductive region disposed over and in electrical contact with the second conductive region, wherein the sixth conductive region is substantially circular, and wherein the sixth conductive region is located within the second window region;
a seventh conductive region disposed over and in electrical contact with the third conductive region, wherein the seventh conductive region is substantially circular, and wherein the seventh conductive region is located within the second window region; and
an eighth conductive region disposed over and in electrical contact with the fourth conductive region, wherein the eighth conductive region is substantially circular, and wherein the eighth conductive region is located within the second window region;
a set of vias, wherein each via from the set of via extends through the package substrate between at least one of the first and fifth conductive regions, the second and sixth conductive regions, the third and seventh conductive regions, and the fourth and eighth conductive regions;
a second metallization layer disposed over the first metallization layer, wherein the second metallization layer includes:
a third window region that is substantially aligned with the second window region;
a ninth conductive region disposed over and in electrical contact with the fifth conductive region, wherein the ninth conductive region is substantially circular, and wherein the ninth conductive region is located within the third window region;
a tenth conductive region disposed over and in electrical contact with the sixth conductive region, wherein the tenth conductive region is substantially circular, and wherein the tenth conductive region is located within the third window region;
an eleventh conductive region disposed over and in electrical contact with the seventh conductive region, wherein the eleventh conductive region is substantially circular, and wherein the eleventh conductive region is located within the third window region;
a twelfth conductive region disposed over and in electrical contact with the eighth conductive region, wherein the twelfth conductive region is substantially circular, and wherein the twelfth conductive region is located within the third window region; and
a thirteenth conductive region that extends between and is in electrical contact with the ninth and twelfth conductive regions; and
a third metallization layer disposed over the second metallization layer, wherein the third metallization layer includes:
a fourth window region that is substantially aligned with the third window region;
a fourteenth conductive region disposed over and in electrical contact with the ninth conductive region, wherein the fourteenth conductive region is substantially circular, and wherein the fourteenth conductive region is located within the fourth window region;
a fifteenth conductive region disposed over and in electrical contact with the tenth conductive region, wherein the fifteenth conductive region is substantially circular, and wherein the fifteenth conductive region is located within the fourth window region;
a sixteenth conductive region disposed over and in electrical contact with the eleventh conductive region, wherein the sixteenth conductive region is substantially circular, and wherein the sixteenth conductive region is located within the fourth window region;
a seventeenth conductive region disposed over and in electrical contact with the twelfth conductive region, wherein the sixteenth conductive region is substantially circular, and wherein the sixteenth conductive region is located third the fourth window region; and
an eighteenth conductive region that extends between and is in electrical contact with the fifteenth and sixteenth conductive regions, wherein the eighteenth region overlaps the thirteenth region.

9. The apparatus of claim 8, wherein the first, second, third, and fourth window regions are substantially rectangular.

10. The apparatus of claim 9, wherein the set of via further comprises a first set of vias, and wherein the antenna package further comprises:
a second set of vias, wherein each via from the second set of via extends between at least one of the ninth and fifth conductive regions, the tenth and sixth conductive regions, the eleventh and seventh conductive regions, and the twelfth and eighth conductive regions; and
a third set of vias, wherein each via from the third set of via extends between at least one of the ninth and fourteenth conductive regions, the tenth and fifteenth conductive regions, the eleventh and sixteenth conductive regions, and the twelfth and seventeenth conductive regions.

11. The apparatus of claim 10, wherein the IC further comprises a plurality of border stud bumps, and wherein the first metallization layer further comprises a nineteenth conductive region that substantially surrounds the first window region and is in electrical contact with the boarder stud bumps, and wherein the second metallization layer further comprises a twentieth conductive region that substantially surrounds the second window region and that is in electrical contact with the nineteenth conductive region, and wherein the third metallization layer further comprises a twenty-first conductive region that substantially surrounds the third window region and that is in electrical contact with the twentieth conductive region.

12. The apparatus of claim 11, wherein the antenna package further comprises:
a fourth set of vias, wherein each via from the fourth set of vias extends between the nineteenth and twentieth conductive regions; and
a fifth set of vias, wherein each via from the fifth set of vias extends between the twentieth and twenty-first conductive regions.

13. The apparatus of claim 12, wherein the first, second, third, and fourth metallization layers are formed of copper or aluminum, and wherein the dielectric layer is formed of polyimide, and wherein each of the first, second, third, fourth, and border stud bumps are formed of gold with a gold-nickel plating.

14. An apparatus comprising:
an integrated circuit (IC) having:
a plurality of RF transceivers;
a plurality of sets of stub bumps, wherein each set of stud bump is associated with at least one of the RF transceivers, and wherein each set of stud bumps includes:
a first stud bump that is coupled to its associated RF transceiver;
a second stud bump that is coupled to its associated RF transceiver;
a third stud bump that is coupled to its associated RF transceiver and that is coupled to ground; and
a fourth stud bump that is coupled to its associated RF transceiver and that is coupled to ground;
an antenna package having:
a dielectric layer, wherein each stud bump from each set of the plurality of sets of stud bumps extends through the dielectric layer;
an underfill layer that is disposed between the dielectric layer and the IC;
a package substrate;
an array of antenna, wherein each antenna is associated with at least of the RF transceivers, and wherein each antenna includes:
a first metallization layer disposed over the substrate, wherein the first metallization layer includes:
a first window region;
a first conductive region disposed over and in electrical contact with its associated first stud bump, wherein the first conductive region is substantially circular, and wherein the first conductive region is located within the first window region;
a second conductive region disposed over and in electrical contact with its associated second stud bump, wherein the second conductive region is substantially circular, and wherein the first conductive region is located within the first window region;
a third conductive region disposed over and in electrical contact with its associated third stud bump, wherein the third conductive region is substantially circular, and wherein the third conductive region is located within the first window region; and
a fourth conductive region disposed over and in electrical contact with its associated fourth stud bump, wherein the fourth conductive region is substantially circular, and wherein the fourth conductive region is located within the first window region;
a second metallization layer disposed over the package substrate, wherein the first metallization layer includes:
a second window region that is substantially aligned with the first window region;
a fifth conductive region disposed over and in electrical contact with the first conductive region, wherein the fifth conductive region is substantially circular, and wherein the fifth conductive region is located within the second window region;
a sixth conductive region disposed over and in electrical contact with the second conductive region, wherein the sixth conductive region is substantially circular, and wherein the sixth conductive region is located within the second window region;
a seventh conductive region disposed over and in electrical contact with the third conductive region, wherein the seventh conductive region is substantially circular, and wherein the seventh conductive region is located within the second window region; and
an eighth conductive region disposed over and in electrical contact with the fourth conductive region, wherein the eighth conductive region is substantially circular, and wherein the eighth conductive region is located within the second window region;
a set of vias, wherein each via from the set of via extends through the package substrate between at least one of the first and fifth conductive regions, the second and sixth conductive regions, the third and seventh conductive regions, and the fourth and eighth conductive regions;
a second metallization layer disposed over the first metallization layer, wherein the second metallization layer includes:
a third window region that is substantially aligned with the second window region;
a ninth conductive region disposed over and in electrical contact with the fifth conductive region, wherein the ninth conductive region is substantially circular, and wherein the ninth conductive region is located within the third window region;
a tenth conductive region disposed over and in electrical contact with the sixth conductive region, wherein the tenth conductive region is substantially circular, and wherein the tenth conductive region is located within the third window region;
an eleventh conductive region disposed over and in electrical contact with the seventh conductive region, wherein the eleventh conductive region is substantially circular, and wherein the eleventh conductive region is located within the third window region;
a twelfth conductive region disposed over and in electrical contact with the eighth conductive region, wherein the twelfth conductive region is substantially circular, and wherein the twelfth conductive region is located within the third window region; and
a thirteenth conductive region that extends between and is in electrical contact with the ninth and twelfth conductive regions; and
a third metallization layer disposed over the second metallization layer, wherein the third metallization layer includes:
a fourth window region that is substantially aligned with the third window region;
a fourteenth conductive region disposed over and in electrical contact with the ninth conductive region, wherein the fourteenth conductive region is substantially circular, and wherein the fourteenth conductive region is located within the fourth window region;
a fifteenth conductive region disposed over and in electrical contact with the tenth conductive region, wherein the fifteenth conductive region is substantially circular, and wherein the fifteenth conductive region is located within the fourth window region;
a sixteenth conductive region disposed over and in electrical contact with the eleventh conductive region, wherein the sixteenth conductive region is substantially circular, and wherein the sixteenth conductive region is located within the fourth window region;
a seventeenth conductive region disposed over and in electrical contact with the twelfth conductive region, wherein the sixteenth conductive region is substantially circular, and wherein the sixteenth conductive region is located third the fourth window region; and
an eighteenth conductive region that extends between and is in electrical contact with the fifteenth and sixteenth conductive regions,
wherein the eighteenth region overlaps the thirteenth region; and
a high impedance surface (HIS) disposed on the substrate and substantially surrounding the array of antennas.

15. The apparatus of claim 14, wherein the first, second, third, and fourth window regions for each antenna are substantially rectangular.

16. The apparatus of claim 15, wherein the set of via further comprises a first set of vias, and wherein the antenna package further comprises:
a second set of vias, wherein each via from the second set of via extends between at least one of the ninth and fifth conductive regions, the tenth and sixth conductive regions, the eleventh and seventh conductive regions, and the twelfth and eighth conductive regions; and
a third set of vias, wherein each via from the third set of via extends between at least one of the ninth and fourteenth conductive regions, the tenth and fifteenth conductive regions, the eleventh and sixteenth conductive regions, and the twelfth and seventeenth conductive regions.

17. The apparatus of claim 16, wherein the IC further comprises a plurality of border stud bumps associated with each RF transceiver, and wherein the first metallization layer for each antenna further comprises a nineteenth conductive region that substantially surrounds the first window region and is in electrical contact with the boarder stud bumps, and wherein the second metallization layer for each antenna further comprises a twentieth conductive region that substantially surrounds the second window region and that is in electrical contact with the nineteenth conductive region, and wherein the third metallization layer for each antenna further comprises a twenty-first conductive region that substantially surrounds the third window region and that is in electrical contact with the twentieth conductive region.

18. The apparatus of claim 17, wherein the antenna package further comprises:
a fourth set of vias, wherein each via from the fourth set of vias extends between the nineteenth and twentieth conductive regions; and
a fifth set of vias, wherein each via from the fifth set of vias extends between the twentieth and twenty-first conductive regions.

19. The apparatus of claim 18, wherein the first, second, third, and fourth metallization layers for each antenna are formed of copper or aluminum, and wherein the dielectric layer is formed of polyimide, and wherein each of the first, second, third, fourth, and border stud bumps are formed of gold with a gold-nickel contact layer.
